(19) United States
(12) Patent Application Publication
(10) Pub. No.: US 2007/0148946 A1
(43) Pub. Date: Jun. 28, 2007

(54) Multi-layered metal wiring structure of semiconductor device and manufacturing method thereof

(75) Inventor: Jung Joo Kim, Seoul (KR)

Correspondence Address: MAYER, BROWN, ROWE & MAW LLP, 1909 K STREET, N.W., WASHINGTON, DC, 20006, US

(73) Assignee: Dongbu Electronics Co., Ltd.

(21) Appl. No.: 11/644,837

(22) Filed: Dec. 26, 2006

(30) Foreign Application Priority Data
Dec. 27, 2005 (KR) 10-2005-0130750

(51) Int. Cl. H01L 21/44

(52) U.S. Cl. 438/597; 438/584

(57) ABSTRACT

A multi-layered metal wiring structure of a semiconductor device includes an interlayer insulating film including an oxide film, a titanium oxide film deposited on the interlayer insulating film, and an aluminum film deposited on the titanium oxide film. The interlayer insulating film includes a FSG film and a silicon oxide film deposited on the FSG film.

### FIELD OF THE INVENTION

The present invention relates to a manufacturing method of a semiconductor device and, more particularly, to a multi-layered metal wiring structure having a titanium oxide film under an aluminum layer, wherein the titanium oxide film is capable of preventing a diffusion of fluorine components of an interlayer insulating film into the aluminum film. Furthermore, the present invention also relates to a manufacturing method of the multi-layered metal wiring structure, wherein the titanium oxide film is formed by heat-treating a titanium film formed under the aluminum layer.

### BACKGROUND OF THE INVENTION

Recently, many active researches have been conducted to develop a wiring technique using copper (Cu), and the range of its application is extending. However, copper wiring has many problems yet to be solved in the aspect of costs and yield. Thus, in general, aluminum (Al) is still widely employed as a wiring material for the fabrication of a memory product, etc.

As for an aluminum wiring, however, because an adhesive strength of aluminum with insulating films, which are located on and under an aluminum film, is low, an upper film and a lower titanium (Ti) film are typically formed on and under the aluminum film, respectively. Also, a titanium nitride (TiN) film, to be used as an antireflection film during an exposure process, is deposited on the upper titanium film. As described, the conventional aluminum wiring has a multi-layered structure that includes the lower titanium film, the aluminum film, the upper titanium film and the titanium nitride film, deposited in this sequence. Here, since titanium and aluminum tend to be readily oxidized when they are exposed to air, the multi-layered structure is formed by successively forming the individual films in an equipment without vacuum break, thus preventing oxidation of the films and moisture permeation at interfaces between them.

Meanwhile, FSG (fluorinated silica glass) has been recently used as a material for forming an interlayer insulating film of the metal wiring. The FSG has a dielectric constant of about 3.5, which is lower than the dielectric constant of a conventional interlayer insulating film formed of silicon oxide (SiO₂). If the dielectric constant of an interlayer insulating film is high, it would result in increases of parasitic capacitance and an RC delay period with a reduction of operating speed of the semiconductor device. Thus, the interlayer insulating film is preferred to have a lower dielectric constant, and on that ground, the FSG has been given attention.

However, the FSG has a problem in that fluorine from the FSG readily diffuses into another film. Thus, in order to use the FSG as an interlayer insulating film, the problem of the diffusion of the fluorine should be solved.

FIGS. 1A and 1B are cross sectional views showing a conventional multi-layered metal wiring structure of a semiconductor device.

Referring to FIG. 1A, a FSG film 11 and a silicon oxide film 12 are first formed as underlying interlayer insulating films below the metal wiring structure through a depositing and a planarizing process. Subsequently, a first titanium film 13, an aluminum film 14, a second titanium film 15 and a titanium nitride film 16 are successively formed to be used as the multi-layered metal wiring structure.

However, since fluorine components in the FSG film 11 tend to move vertically and horizontally, they would be exposed on the surface of the silicone nitride film 12 or even diffused into the aluminum film 14 after penetrating the first titanium film 13. Thus diffused fluorine components would generate fluoric acid (HF), melting the silicon oxide film 12 and the aluminum film 14. As a result, reliability problems such as an open circuit fault and a short circuit fault would be caused. Furthermore, if the fluorine components are present on the surface of the silicon oxide film 12, the adhesion between the first titanium film 13 and the silicon oxide film 12 would be weakened, causing the multi-layered metal wiring structure to get loose with gaps created between its films 12 and 13.

Meanwhile, if the titanium films 13 and 15 are reacted with the aluminum film 14 during a subsequent processing using heat, titanium aluminum (TiAl₃) films 13a and 15a are generated by the reaction. The titanium aluminum films 13a and 15a not only deteriorate electrical characteristics of the device by increasing a contact sheet resistance of the metal wiring but also cause various reliability problems such as generation of SIVs (stress-induced voids), EM (electromigration) phenomenon, etc.

### SUMMARY OF THE INVENTION

It is, therefore, an object of the present invention to provide: a multi-layered metal wiring structure capable of preventing a diffusion of fluorine of an interlayer insulating film and also preventing an occurrence of various reliability problems that might be caused as a result of a formation of a titanium aluminum film; and a manufacturing method of such a metal wiring structure.

In accordance with a first aspect of the present invention, there is provided a multi-layered metal wiring structure of a semiconductor device, including: an interlayer insulating film including an oxide film; a titanium oxide film deposited on the interlayer insulating film; and an aluminum film deposited on the titanium oxide film.

In accordance with a second aspect of the present invention, there is provided a method for forming a multi-layered metal wiring structure of a semiconductor device, including the steps of: forming an interlayer insulating film including an oxide film; forming a first titanium film on the interlayer insulating film; forming a titanium oxide film by heat-treating the first titanium film; and forming an aluminum film on the titanium oxide film.

### BRIEF DESCRIPTION OF THE DRAWINGS

The above and other objects and features of the present invention will become apparent from the following description of preferred embodiments, given in conjunction with the accompanying drawings, in which:

FIGS. 1A and 1B set forth cross sectional views showing a conventional multi-layered metal wiring structure of a semiconductor device; and

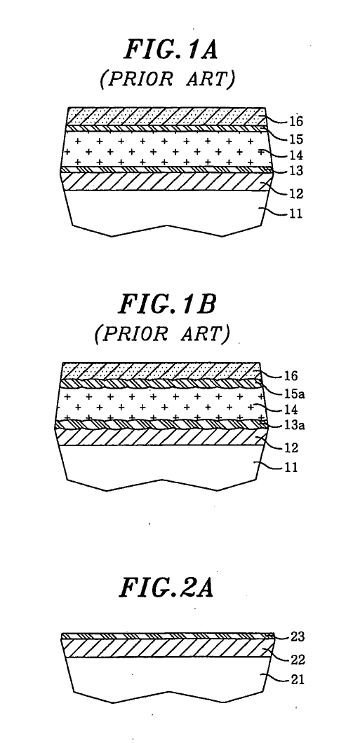

FIGS. 2A to 2D present cross sectional views illustrating a multi-layered metal wiring structure of a semiconductor device and a manufacturing method thereof in accordance with a preferred embodiment of the present invention.

### DETAILED DESCRIPTION OF THE DRAWINGS

Hereinafter, preferred embodiments of the present invention will be described in detail in conjunction with the accompanying drawings.

In describing the preferred embodiment, explanation of technical conceptions already known in the art or considered to be irrelevant to the present invention will be omitted for the simplicity of explanation because there is a concern that their explanation would make the essence of the present invention obscure rather than clarifying it. For the same reason, some components are exaggerated in their sizes, omitted or drawn schematically in the drawings, so it is to be noted herein that the components may not be viewed in their real sizes here.

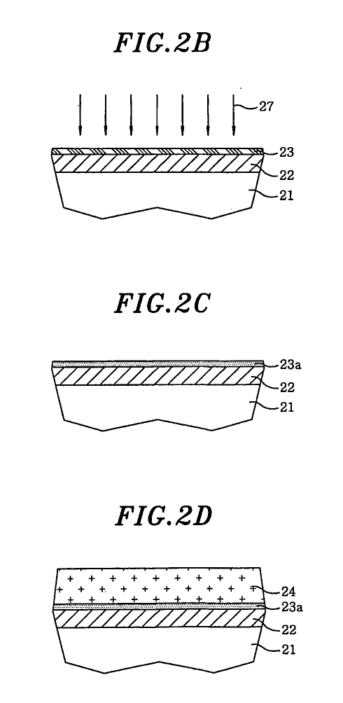

FIGS. 2A to 2D provide cross sectional views illustrating a multi-layered metal wiring structure and a manufacturing method thereof in accordance with the preferred embodiment of the present invention.

First, as shown in FIG. 2A, a FSG film 21 and a silicon oxide film 22 are successively formed in that order and planarized thereafter, to be used as underlying interlayer insulating films of a metal wiring structure. A first titanium film 23 is formed on the interlayer insulating film including the FSG film 21 and the silicon oxide film 22.

Subsequently, as illustrated in FIG. 2B, an annealing process is conducted at a temperature ranging from about 300° C. to 450° C. (e.g., about 400° C.) by using an oxygen/ozone (O₂/O₃) plasma 27. Through the annealing process, the first titanium film 23 is converted into a thin titanium oxide film (TiO₂) 23a. that acts as a barrier metal layer, as shown in FIG. 2C. Because the titanium oxide film 23a has a very high film quality and solidity, it can prevent fluorine components of the FSG film 21 from penetrating, and, furthermore, it may not suffer deterioration in its adhesive strength with the underlying silicon oxide film.

Thereafter, as shown in FIG. 2D, an aluminum film 24 is formed on the titanium oxide film 23a. Since the titanium oxide film 23a serves as an anti-diffusion film for preventing the diffusion of the fluorine components, the reliability of the aluminum film 24 can be improved, and the aforementioned prior art problems can be avoided. Moreover, since the titanium oxide film 23a reacts with the aluminum film 24, a formation of a titanium aluminum film may be prevented in a subsequent heat-involved process, so that various problems that might be caused due to the presence of the titanium aluminum film may be avoided.

Afterward, though not shown in the drawings, a second titanium film and a titanium nitride film may be formed on the aluminum film in that order, and by performing a photolithographic etching process, a multi-layered metal wiring structure may be finally obtained.

In accordance with the preferred embodiment of the present invention as described above, by forming the titanium oxide film by means of heat-treating the titanium film formed under the aluminum film, fluorine within the interlayer insulating film may be prevented from diffusing into the aluminum layer. Thus, wiring faults due to the diffusion of the fluorine may be prevented, and deterioration in adhesive strength between the films may be avoided.

Furthermore, by preventing a generation of a titanium aluminum film, an increase of a contact sheet resistance of the metal wiring may be prevented, and various reliability problems such as creation of stress-induced voids and an electromigration phenomenon may be avoided.

While the invention has been shown and described with respect to the preferred embodiments, it will be understood by those skilled in the art that various changes and modifications may be made without departing from the spirit and scope of the invention as defined in the following claims.

What is claimed is:

1. A multi-layered metal wiring structure of a semiconductor device, comprising:
an interlayer insulating film including an oxide film;
a barrier metal layer deposited on the interlayer insulating film; and
an aluminum film deposited on the barrier metal layer.

2. The structure of claim 1, wherein the interlayer insulating film includes a FSG (fluorinated silica glass) film and a silicon oxide film deposited on the FSG film.

3. The structure of claim 1, wherein the barrier metal layer includes a titanium oxide film.

4. The structure of claim 1, further comprising a titanium film and a titanium nitride film deposited on the aluminum film in this order.

5. A method for forming a multi-layered metal wiring structure of a semiconductor device, comprising the steps of:
(a) forming an interlayer insulating film including an oxide film;
(b) forming a first titanium film on the interlayer insulating film;
(c) forming a barrier metal layer by heat-treating the first titanium film; and
(d) forming an aluminum film on the barrier metal layer.

6. The method of claim 5, wherein the step (a) includes forming a FSG film and a silicon oxide film in this order and planarizing them thereafter.

7. The method of claim 5, wherein the step (c) is performed at a temperature ranging from about 300° C. to 450° C. by using an oxygen/ozone plasma.

8. The method of claim 5, wherein the barrier metal layer includes a titanium oxide film.

9. The method of claim 5, further comprising forming a second titanium film and a titanium nitride film successively in this order after completing the step (d).
